(19) United States
(12) Patent Application Publication
(10) Pub. No.: US 2019/0221691 A1
(43) Pub. Date: Jul. 18, 2019

(54) PHOTOABSORBER AND SOLAR CELL COMPRISING THE SAME

(71) Applicant: Panasonic Intellectual Property Management Co., Ltd., Osaka (JP)

(72) Inventors: TOMOYASU YOKOYAMA, Osaka (JP); MICHIO SUZUKA, Kyoto (JP)

(21) Appl. No.: 16/203,673

(22) Filed: Nov. 29, 2018

(30) Foreign Application Priority Data
Jan. 17, 2018 (JP) 2018-005654

(51) Int. Cl. H01L 31/032; H01L 31/0224; H01L 31/18

(52) U.S. Cl. CPC H01L 31/032; H01L 31/18; H01L 31/022425

(57) ABSTRACT

The present disclosure provides a photoabsorber containing:
a perovskite compound represented by the composition formula ABX₃,
   where
   A represents a monovalent cation,
   B represents a divalent cation including a Sn cation, and
   X represents a halogen anion; and
a metal Sn.

### BACKGROUND

### 1. Technical Field

The present disclosure relates to a photoabsorber and a solar cell comprising the same.

### 2. Description of the Related Art

A perovskite solar cell has been recently researched and developed. In the perovskite solar cell, a perovskite compound formed of a perovskite crystal structure represented by the composition formula ABX₃ (where A is a monovalent cation, B is a divalent cation, and X is a halogen anion) or a structure similar thereto is used as a photoabsorber.

Non-Patent Literature 1 discloses that a perovskite compound represented by CH₃NH₃SnI₃ (hereinafter, referred to as “MASnI₃”) is used as a photoabsorber of the perovskite solar cell. Non-Patent Literature 1 also discloses a perovskite compound represented by (NH₂)₂CHSnI₃ (hereinafter, referred to as “FASnI₃”). In the instant specification, a perovskite compound containing Sn cation as a divalent cation is referred to as “Sn-type perovskite compound”.

### CITATION LIST

### Non-Patent Literature

Non-Patent Literature 1: Shuyan Shao et. Al. “Highly Reproducible Sn-Based Hybrid Perovskite Solar Cells with 9% Efficiency”, Advanced Energy Materials, 2018, Vol. 8, 1702019

Non-Patent Literature 2: Mulmudi Hemant Kumar et al., “Lead-Free Halide Perovskite Solar Cells with High Photocurrents Realized Through Vacancy Modulation”, Advanced Materials, 2014, Vol. 26, 7122-7127

### SUMMARY

An object of the present disclosure is to provide a photoabsorber having low carrier density.

The present disclosure provides a photoabsorber containing:

a perovskite compound represented by the composition formula ABX₃,
where
A represents a monovalent cation,
B represents a divalent cation including a Sn cation, and
X represents a halogen anion; and

a metal Sn.

The present disclosure provides a photoabsorber having low carrier density.

### BRIEF DESCRIPTION OF THE DRAWINGS

FIG. 1 is a graph showing a relation between the carrier density of a photoabsorber layer of the solar cell and the conversion efficiency of the solar cell.

FIG. 2 is a graph showing a relation between the chemical potential of Sn and vacancy-forming energy of Sn vacancies in the perovskite compound when the Sn-type perovskite compound coexists together with a Sn compound and a metal Sn, the graph being drawn on the basis of the first principle calculation.

FIG. 3A shows a schematic view of one step included in one example of a fabrication method of the photoabsorber of the present disclosure.

FIG. 3B shows a schematic view of one step included in one example of a fabrication method of the photoabsorber of the present disclosure, apart from the step shown in FIG. 3A.

FIG. 3C shows a schematic view of one step included in one example of a fabrication method of the photoabsorber of the present disclosure, subsequently to FIG. 3A and FIG. 3B.

FIG. 4 is a cross-sectional view of the first example of the solar cell according to the present embodiment.

FIG. 5 is a cross-sectional view of the second example of the solar cell according to the present embodiment.

FIG. 6 is a cross-sectional view of the third example of the solar cell according to the present embodiment.

FIG. 7 is a cross-sectional view of the fourth example of the solar cell according to the present embodiment.

FIG. 8A is graph showing the XRD measurement results provided in the inventive examples 1-4 and the comparative example 1.

FIG. 8B is graph showing the XRD measurement results provided in the inventive examples 1-4 and the comparative example 1.

FIG. 9 is a graph showing the results of the light-transmissivity of the films of the photoabsorbers of the inventive examples 1-4 and the comparative example 1.

### DETAILED DESCRIPTION OF THE EMBODIMENT

Hereinafter, the embodiment of the present disclosure will be described with reference to the drawings.

(Findings Which Established the Foundation of the Present Disclosure)

The findings which established the foundation of the present disclosure will be described below.

A Sn-type perovskite compound is one of suitable materials used as a photoabsorber of a solar cell, since the Sn-type perovskite compound has a bandgap in the vicinity of 1.4 eV. However, in the Sn-type perovskite compound, a part of the B site occupied by Sn²⁺ is a vacancy. The generation of the vacancy by Sn²⁺ increases the carrier density to a high value of 10¹⁹ cm⁻³. As a result, the Sn-type perovskite compound exhibits not an i-type property but a p-type property. Hence, when the Sn-type perovskite compound is used as a photoabsorber of a solar cell without any change, an appropriate p-i-n junction is not achieved. This lowers conversion efficiency of the solar cell.

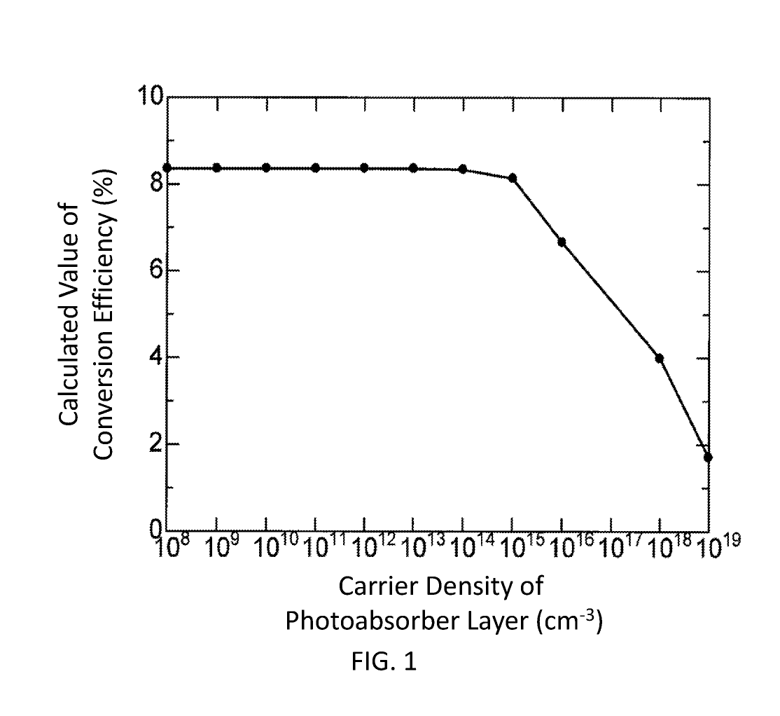

Non-patent Literature 2 reports that the addition of SnF₂ to the Sn-type perovskite compound lowers the carrier density to 10¹⁸ cm⁻³ to improve the conversion efficiency. However, the carrier density is required to be lowered more to achieve the p-i-n junction optimum for the conversion efficiency improvement. FIG. 1 is a graph showing a relation between the carrier density of a photoabsorber layer of the solar cell and the conversion efficiency of the solar cell. The relation is calculated with device simulation. The results shown in FIG. 1 reveal that the carrier density of the photoabsorber layer is required to be lowered to not more than 10¹⁵ cm⁻³ to provide high conversion efficiency. Therefore, it is required to lower the carrier density of the Sn-type perovskite compound.

The present inventors found that a perovskite compound is prepared using a metal Sn as a starting material to lower the carrier density of the Sn-type perovskite compound. Furthermore, the present inventors found that a metal Sn is added to the Sn-type perovskite compound to lower the carrier density of the Sn-type perovskite compound. On the basis of these findings, the present inventors invented a photoabsorber containing the Sn-type perovskite compound and having low carrier density. The present inventors also invented a solar cell using the photoabsorber.

(Composition and Crystal Structure of Perovskite Compound)

The photoabsorber according to the present embodiment of the present disclosure contains a perovskite compound represented by the composition formula ABX₃ and a metal Sn. A represents a monovalent cation, B represents a divalent cation including a Sn cation, and X represents a halogen anion. Hereinafter, such a perovskite compound is referred to as the perovskite compound according to the present embodiment. Pursuant to the expression used conventionally for the perovskite compound, A, B, and X are referred to as “A site”, “B site”, and “X site” in the instant specification, respectively. In the instant specification, the word “photoabsorber” means “light absorbing material”. In addition, the photoabsorber serves as a photoelectric conversion material.

The perovskite compound according to the present embodiment has a perovskite crystal structure represented by the composition formula ABX₃. For example, in the above composition formula, A is a monovalent cation, B is a Sn cation, and X is a halogen anion. In other words, in the perovskite compound according to the present embodiment, for example, the monovalent cation is located at the A site, Sn²⁺ is located at the B site, and the halogen anion is located at the X site.

The monovalent cation located at the A site is not particularly limited. An example of the monovalent cation is an organic cation or an alkali metal cation. For example, the monovalent cation includes at least one selected from the group consisting of a methylammonium cation (i.e., CH₃NH₃⁺), a formamidinium cation (i.e., NH₂CHNH₂⁺), a cesium cation (Cs⁺), a phenylethylammonium cation (C₆H₅C₂H₄NH₃⁺), and a guanidinium cation (CH₆N₃⁺). The monovalent cation is, for example, a formamidinium cation. The halogen anion located at the X site is, for example, an iodide anion. Each of the A site, the B site, and the X site may be occupied by plural kinds of ions.

In the present embodiment, the metal Sn is present in the photoabsorber. As long as the metal Sn is present in the photoabsorber of the present embodiment, the metal Sn may be dispersed in the state of the fine particles or may be segregated in a part of the photoabsorber.

When the photoabsorber according to the present embodiment is subjected to an X-ray diffraction measurement using a CuKα ray, the resultant X-ray diffraction pattern may have the following characteristics. Hereinafter, the term “first range” means a range within which a diffraction angle is not less than 24.2° and not more than 24.4°. The term “second range” means a range within which a diffraction angle is not less than 30.5° and not more than 30.7°. A peak position derived from the perovskite compound according to the present embodiment is included in the first range. A peak position derived from the metal Sn is included in the second range.

In the X-ray diffraction pattern of the photoabsorber according to the present embodiment, a ratio of the maximum diffraction intensity within the second range to the maximum diffraction intensity within the first range may be more than 48% and less than 1,130%. Hereinafter, the ratio is referred to as “Intensity ratio”. The intensity ratio may be not less than 80% and not more than 510%. Since the photoabsorber having an intensity ratio of more than 48% has low carrier density, the solar cell including the photoabsorber has high conversion efficiency. The photoabsorber having an intensity ratio of less than 1,130% suppresses the decrease of the light-transmissivity which is due to reflection of the metal Sn contained in the perovskite solar cell to achieve higher conversion efficiency.

The photoabsorber according to the present embodiment contains the perovskite compound according to the present embodiment and the metal Sn. Hence, the above-mentioned X-ray diffraction pattern of the photoabsorber according to the present embodiment may have peaks within the first and second ranges.

In the composition analysis result of the photoabsorber according to the present embodiment using an X-ray photoelectron spectroscopic measurement, a molar ratio of Sn to the halogen may be more than 0.317 and not more than 0.986.

The photoabsorber according to the present embodiment may contain the perovskite compound according to the present embodiment mainly; however, may contain impurities. A weight ratio of the perovskite compound to the photoabsorber may be not less than 80% mass. The photoabsorber according to the present embodiment may further contain a compound other than the perovskite compound according to the present embodiment.

(Property of Perovskite Compound)

The perovskite compound according to the present embodiment has the following carrier density as a useful property in the photoabsorber for the solar cell.

The perovskite compound according to the present embodiment may have less than ten-thousandth times lower carrier density than conventional Sn-type perovskite compounds. The perovskite compound according to the present embodiment may have a carrier density of not more than 10¹⁵ cm⁻³, or not less than 10⁹ cm⁻³ and not more than 10¹⁵ cm⁻³.

The carrier density of the perovskite compound may be calculated on the basis of results of hole effect measurement or impedance measurement of the perovskite compound.

Hereinafter, the present inventors describe the reason why the perovskite compound according to the present embodiment has a lower carrier density than the conventional Sn-type perovskite compounds. The present inventors describe the reason as below, for example, on the basis of chemical potential of Sn in the perovskite compound.

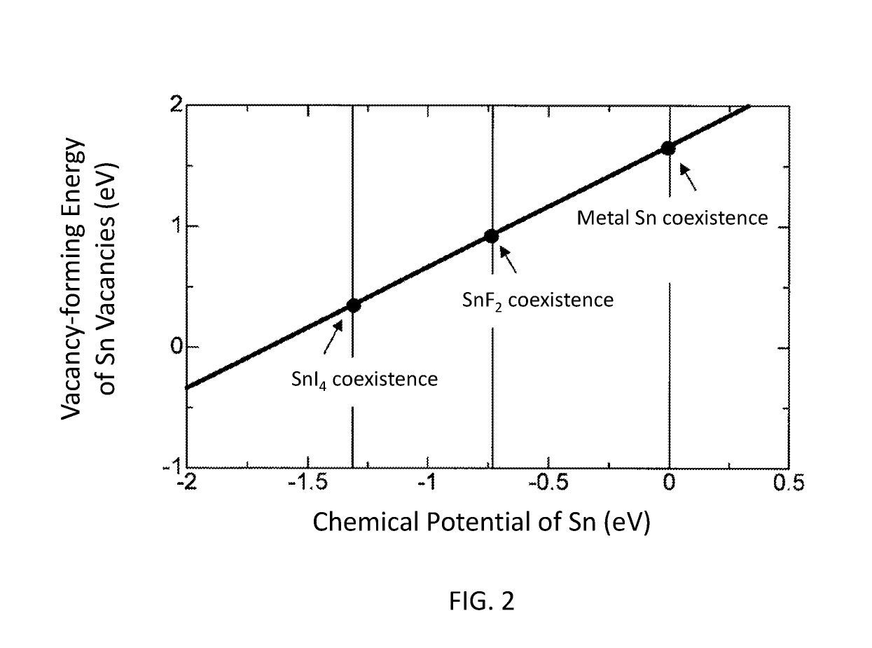

FIG. 2 is a graph showing a relation between the chemical potential of Sn and vacancy-forming energy of Sn vacancies in the perovskite compound when the Sn-type perovskite compound coexists together with a Sn compound and a metal Sn. FIG. 2 is drawn on the basis of the first principle calculation. When the vacancy-forming energy of Sn vacancies is low, a lot of the vacancies are present in the perovskite compound. In the calculation result, there is no relation between the amounts of the Sn compound and the metal Sn, both of which coexists together.

In a case of “SnI₄ coexistence”, Sn²⁺ contained in the perovskite compound is oxidized to generate Sn⁴⁺. As a result, the chemical potential of Sn is low. Hence, the vacancy-forming energy of the Sn vacancies is low, and the Sn vacancies are generated relatively easily. The Sn vacancies are sites which generates holes. For this reason, due to the Sn vacancies, the Sn-type perovskite compound exhibits a property of a p-type semiconductor. Even when the Sn-type perovskite compound is left at rest without contact with other compounds, the compound containing a tetravalent Sn cation is easily generated. Therefore, the result corresponds to the case where the Sn-type perovskite compound exists alone. In a case of “SnF₂ coexistence”, namely, in a case where SnF₂ and the perovskite compound coexist, the chemical potential of Sn is increased to −0.8 eV and the vacancy-forming energy of the Sn vacancies is high. Due to the existence of SnF₂, the Sn vacancies are difficult to generate. Therefore, as reported in Non-patent Literature 2, SnF₂ is added to the Sn-type perovskite compound at a starting composition ratio of 10% to decrease the carrier density to less than one-tenth. On the other hand, when the Sn-type perovskite compound coexists together with the metal Sn, the chemical potential of Sn is the highest. In this case, the vacancy-forming energy of the Sn vacancies is increased significantly. Therefore, due to the existence of the metal Sn, the carrier density is lowered to not more than 10¹⁵ cm⁻³. As a result, the photoabsorber according to the present embodiment is expected to achieve high conversion efficiency, when the photoabsorber is used as a photoabsorber for the solar cell.

(Fabrication Method of Photoabsorber)

Hereinafter, a fabrication method of the photoabsorber according to the present embodiment will be described with reference to the drawings. Now, as one example, a crystal growth method in a liquid phase will be described; however, the fabrication method of the photoabsorber according to the present embodiment is not limited. The photoabsorber of the present embodiment can be fabricated by a solution coating method or a liquid-phase synthesis method. In the following description, as one example, a fabrication method of the photoabsorber containing the perovskite compound of FASnI₃ and the metal Sn will be described.

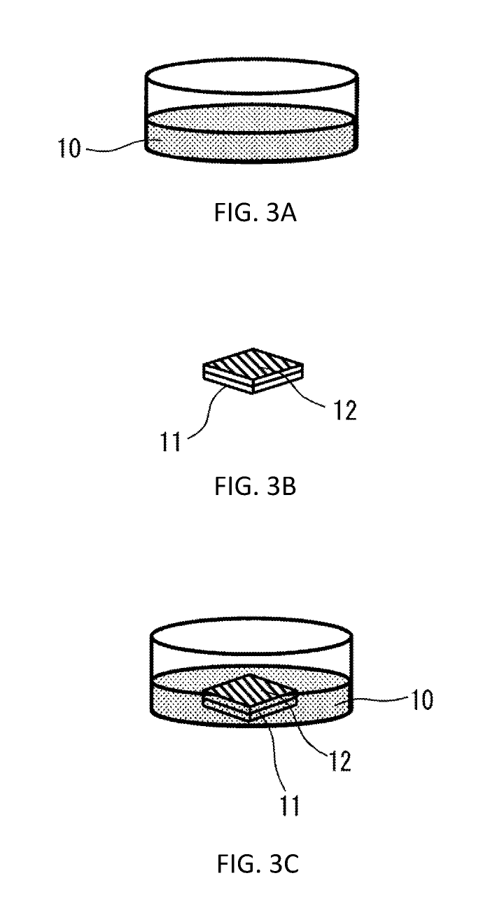

First, as shown in FIG. 3A, HC(NH₂)₂I (hereinafter, referred to as “FAI”) and I₂ are added to an organic solvent to prepare a mixture solution. The molar number of FAI is equal to that of I₂. An example of the organic solvent is alcohol, ether, lactone, alkylsulfoxide, or amido. A plurality of kinds of solvents may be mixed in the organic solvent. In addition, an example of the organic solvent is butanol, diethyl ether, dimethyl sulfoxide (hereinafter, referred to as “DMSO”), or N,N-dimethylformamide (hereinafter, referred to as “DMF”). While the solution is stirred well, the FAI and I₂ are dissolved to prepare a black solution 10 (hereinafter, referred to as “first solution”) containing HC(NH₂)₂I₃ (hereinafter, referred to as “FAI₃”).

Apart from the above, as shown in FIG. 3B, for example, a film of the metal Sn is formed on a substrate 11 by a vapor deposition method to provide a gray metal Sn film 12. The metal Sn film 12 may have a thickness of not less than 50 nanometers and not more than 300 nanometers. In a case where the metal Sn film 12 is too thin, in a later step, all of the metal Sn film 12 may be dissolved in the first solution 10. So, it is desirable that the metal Sn film 12 has the above thickness.

After these, as shown in FIG. 3C, the metal Sn film 12 is immersed in the first solution 10. The temperature of the immersion may be room temperature. The period of the immersion may be not less than one hour. In the state where the metal Sn film 12 is immersed in the first solution 10, oxidation and reduction reaction of Sn and FAI₃ occurs. As a result, the color of the gray metal Sn film 12 is changed to black. In this way, the photoabsorber according to the present embodiment is provided. Subsequently, the photoabsorber according to the present embodiment may be heated on a hot plate maintained at not less than 80 degrees Celsius and not more than 200 degrees Celsius. The period of the heating may be not less than 5 minutes and not more than one hour. In this way, provided is the photoabsorber according to the present embodiment which contains the perovskite compound according to the present embodiment and the metal Sn.

The photoabsorber according to the present embodiment may be fabricated by other fabrication methods. For example, metal Sn powder or a metal Sn film is further mixed to the first solution to prepare a solution, and then, the solution is used to form the photoabsorber of the present embodiment.

(Perovskite Solar Cell)

Hereinafter, the embodiment of the perovskite solar cell according to the present disclosure will be described.

The solar cell according to the present embodiment comprises a first electrode, a second electrode, a photoabsorber layer located between the first electrode and second electrode. The first electrode faces the second electrode in such a manner that the photoabsorber is present between the first electrode and second electrode. At least one electrode selected from the group consisting of the first electrode and the second electrode is light-transmissive. In the instant specification, the sentence “Electrode is light-transmissive” means that not less than 10 percent of light having a wavelength of 200-2,000 nanometers travels through the electrode at a wavelength included therein. The photoabsober layer includes the photoabsober of the present embodiment. Since the solar cell according to the present embodiment includes the photoabsorber according to the present embodiment, the solar cell according to the present embodiment has high conversion efficiency. Hereinafter, four structure examples of the solar cells (first example-fourth example) and the fabrication method thereof will be described with reference to the drawings.

(First Example of Solar Cell)

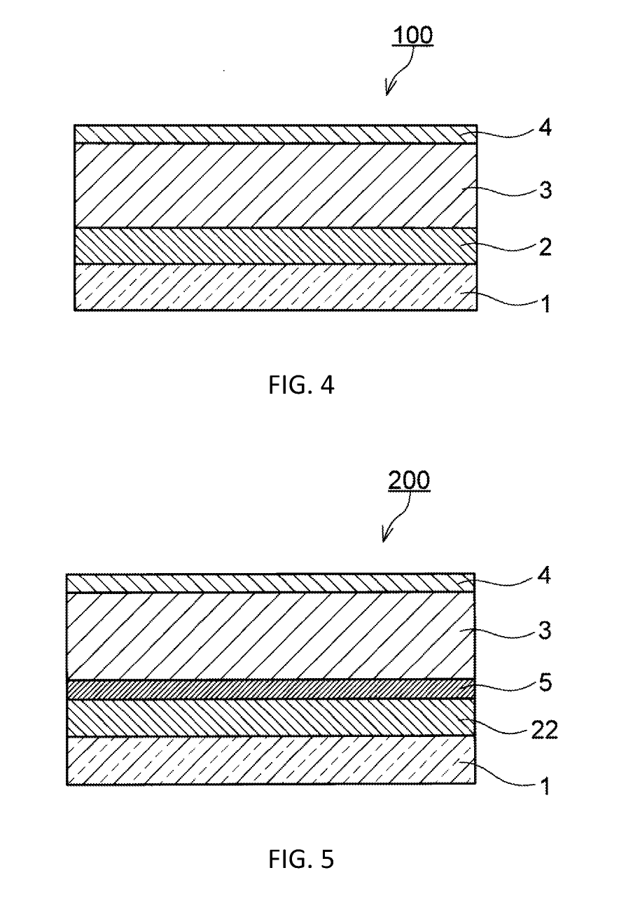

FIG. 4 is a cross-sectional view of the first example of the solar cell according to the present embodiment.

In a solar cell 100, a first electrode 2, a photoabsorber layer 3, and a second electrode 4 are stacked on a substrate 1 in this order. The photoabsorber layer 3 contains the photoabsorber formed of the perovskite compound according to the present embodiment. The solar cell 100 does not have to comprise the substrate 1.

Hereinafter, the fundamental function effect of the solar cell 100 will be described. When the solar cell 100 is irradiated with light, the light is absorbed into the photoabsorber layer 3. As a result, holes and excited electrons are generated in the photoabsorber layer 3. The excited electrons migrate to the first electrode 2. On the other hand, the holes generated in the photoabsorber layer 3 migrate to the second electrode 4. In this way, electric current is taken out from the first electrode 2 and the second electrode 4, which serve as a negative electrode and a positive electrode, respectively.

The solar cell 100 may be fabricated by any one of the following four methods. In the first method, first, the first electrode 2 is formed on the substrate 1 by a chemical vapor deposition method (hereinafter, referred to as a CVD method) or a sputtering method. Next, the photoabsorber layer 3 containing the photoabsorber according to the present embodiment is formed on the first electrode 2 by the method shown in FIG. 3A-FIG. 3C. In the second method, the metal Sn film is formed on the first electrode 2, and then, a solution containing FAI₃ is brought into contact with the metal Sn film to form the photoabsorber layer 3 on the first electrode 2. In the third method, a solution in which a metal Sn has been added to a solution containing FAI₃ is used to form the photoabsorber layer 3 on the first electrode 2. In the fourth method, for example, the substrate 11 is removed from the photoabsorber layer 3 formed by the method shown in FIG. 3A-FIG. 3C, and then, the photoabsorber layer 3 is disposed on the first electrode 2 to form the photoabsorber layer 3 on the first electrode 2. Subsequently, the second electrode 4 is formed on the photoabsorber layer 3 to provide the solar cell 100.

Hereinafter, elements of the solar cell 100 will be described in more detail.

(Substrate 1)

The substrate 1 holds the layers of the solar cell 100. The substrate 1 may be formed of a transparent material. An example of the solar cell 100 is a glass substrate or a plastic substrate. An example of the plastic substrate is a plastic film. When the first electrode 2 has sufficient strength, the photoabsorber layer 3 and the second electrode 4 can be stacked on or above the first electrode 2. Therefore, the solar cell 100 does not have to comprise the substrate 1.

(First Electrode 2)

The first electrode 2 has electric conductivity. The first electrode 2 does not form an ohmic contact with the photoabsorber layer 3. Furthermore, the first electrode 2 has a hole block property that the holes migrating from the photoabsorber layer 3 are blocked. The hole block property is to allow only electrons generated in the photoabsorber layer 3 to travel through the first electrode 2 and to prevent holes generated in the photoabsorber layer 3 from traveling through the first electrode 2. The material having the hole block property is a material having a higher Fermi energy than the energy at the upper end of the valence band of the photoabsorber layer 3. The above material may have a higher Fermi energy than the photoabsorber layer 3. An example of a suitable material for the first electrode 2 required to have the hole block property is aluminum.

The first electrode 2 is light-transmissive. Light from visible light to near-infrared light passes through the first electrode 2, for example. The first electrode 2 may be formed of a transparent and electrically-conductive metal oxide and/or nitride. An example of the material for the first electrode 2 is

(i) titanium oxide doped with at least one selected from the group consisting of lithium, magnesium, niobium, and fluorine;

(ii) gallium oxide doped with at least one selected from the group consisting of tin and silicon;

(iii) gallium nitride doped with at least one selected from the group consisting of silicon and oxygen;

(iv) indium-tin composite oxide;

(v) tin oxide doped with at least one selected from the group consisting of antimony and fluorine;

(vi) zinc oxide doped with at least one selected from the group consisting of boron, aluminum, gallium, and indium; or

(vii) a composite thereof.

The first electrode 2 may be formed by providing a pattern through which light passes using a non-transparent material. An example of the pattern through which the light passes is a line, a wave, a grid, or a punching metal pattern on which a lot of fine through holes are arranged regularly or irregularly. When the first electrode 2 has the above-mentioned pattern, light can travel through a part in which an electrode material is absent. An example of the non-transparent material is platinum, gold, silver, copper, aluminum, rhodium, indium, titanium, iron, nickel, tin, zinc, or alloy containing at least two selected therefrom. An electrically-conductive carbon material may be used as the non-transparent material.

Light-transmissivity of the first electrode 2 is, for example, not less than 50%, or not less than 80%. A wavelength of the light which passes through the first electrode 2 is dependent on a wavelength of the light which is absorbed into the photoabsorber layer 3. The first electrode 2 has a thickness of, for example, not less than 1 nanometer and not more than 1,000 nanometers.

(Photoabsorber Layer 3)

The photoabsorber layer 3 contains the photoabsorber according to the present embodiment. In other words, the photoabsorber of the photoabsorber layer 3 includes the perovskite compound according to the present embodiment and the metal Sn. The photoabsorber layer 3 has a thickness, for example, not less than 100 nanometers and not more than 1,000 nanometers, which is dependent on the magnitude of light absorption of the photoabsorber layer 3. The photoabsorber layer 3 may be formed by cutting a stacking structure comprising the layer containing the photoabsorber according to the present embodiment. The fabrication method of the photoabsorber layer 3 is not limited.

(Second Electrode 4)

The second electrode 4 has electrical conductivity. The second electrode 4 does not form an ohmic contact with the photoabsorber layer 3. Furthermore, the second electrode 4 has an electron block property that the electrons migrating from the photoabsorber layer 3 are blocked. The electron block property is to allow only holes generated in the photoabsorber layer 3 to travel through the second electrode 4 and to prevent electrons generated in the photoabsorber layer 3 from traveling through the second electrode 4. The material having the electron block property is a material having a lower Fermi energy than the energy at the lower end of the conduction band of the photoabsorber layer 3. The above material may have a lower Fermi energy than the photoabsorber layer 3. An example of a suitable material for the second electrode 4 required to have the electron block property is platinum, gold, or a carbon material such as graphene.

(Second Example of Solar Cell)

FIG. 5 is a cross-sectional view of the second example of the solar cell according to the present embodiment. Unlike the solar cell 100 shown in FIG. 4, the solar cell 200 comprises an electron transport layer 5. The common referential signs are assigned to the elements each having the same function and configuration as that of the solar cell 100 and the description thereof will be omitted.

In the solar cell 200, a first electrode 22, the electron transport layer 5, the photoabsorber layer 3, and the second electrode 4 are stacked on the substrate 1 in this order. The solar cell 200 does not have to comprise the substrate 1.

Hereinafter, the fundamental function effect of the solar cell 200 will be described. When the solar cell 200 is irradiated with light, the light is absorbed into the photoabsorber layer 3. As a result, holes and excited electrons are generated in the photoabsorber layer 3. The excited electrons migrate through the electron transport layer 5 to the first electrode 22. On the other hand, the holes generated in the photoabsorber layer 3 migrate to the second electrode 4. In this way, electric current is taken out from the first electrode 22 and the second electrode 4, which serve as a negative electrode and a positive electrode, respectively.

Since the solar cell 200 is provided with the electron transport layer 5, the first electrode 22 does not have to have the hole block property that the holes migrating from the photoabsorber layer 3 are blocked. Therefore, the range of the choice of the material of the first electrode 22 is expanded.

The solar cell 200 may be fabricated in the same way as that of the solar cell 100 shown in FIG. 4. The electron transport layer 5 may be formed on the first electrode 22 by a sputtering method.

Hereinafter, elements of the solar cell 200 will be described in more detail.

(First Electrode 22)

The first electrode 22 has electric conductivity. The first electrode 22 may have the same configuration as the first electrode 2. Since the solar cell 200 comprises the electron transport layer 5, the first electrode 22 does not have to have the hole block property that the holes migrating from the photoabsorber layer 3 are blocked. In other words, the material of the first electrode 22 may be a material capable of being in ohmic contact with the photoabsorber layer 3.

The first electrode 22 is light-transmissive. Light from visible light to near-infrared light passes through the first electrode 22, for example. The first electrode 22 may be formed of a transparent and electrically-conductive metal oxide and/or nitride. An example of the material for the first electrode 22 is

(i) titanium oxide doped with at least one selected from the group consisting of lithium, magnesium, niobium, and fluorine;

(ii) gallium oxide doped with at least one selected from the group consisting of tin and silicon;

(iii) gallium nitride doped with at least one selected from the group consisting of silicon and oxygen;

(iv) indium-tin composite oxide;

(v) tin oxide doped with at least one selected from the group consisting of antimony and fluorine;

(vi) zinc oxide doped with at least one selected from the group consisting of boron, aluminum, gallium, and indium; or

(vii) a composite thereof.

The material of the first electrode 22 may be a non-transparent material. In this case, similarly to the case of the first electrode 2, the first electrode 22 is formed so as to have a pattern through which light travels. An example of the non-transparent material is platinum, gold, silver, copper, aluminum, rhodium, indium, titanium, iron, nickel, tin, zinc, or alloy containing at least two selected therefrom. An electrically-conductive carbon material may be used as the non-transparent material.

Light-transmissivity of the first electrode 22 is, for example, not less than 50%, or not less than 80%. A wavelength of the light which passes through the first electrode 22 is dependent on a wavelength of the light which is absorbed into the photoabsorber layer 3. The first electrode 22 has a thickness of, for example, not less than 1 nanometer and not more than 1,000 nanometers.

(Electron Transport Layer 5)

The electron transport layer 5 contains a semiconductor. The electron transport layer 5 may be formed of a semiconductor having a bandgap of not less than 3.0 eV. Visible light and infrared light travel through the electron transport layer 5 formed of the semiconductor having a bandgap of not less than 3.0 eV to reach the photoabsorber layer 3. An example of the semiconductor is an organic or inorganic n-type semiconductor.

An example of the organic n-type semiconductor is an imide compound, a quinone compound, fullerene, or derivative of fullerene. An example of the inorganic n-type semiconductor is a metal oxide or a perovskite oxide. An example of the metal oxide is an oxide of Cd, Zn, In, Pb, Mo, W, Sb, Bi, Cu, Hg, Ti, Ag, Mn, Fe, V, Sn, Zr, Sr, Ga, Si, or Cr. TiO₂ is desirable. An example of the perovskite oxide is SrTiO₃ or CaTiO₃.

The electron transport layer 5 may be formed of a material having a bandgap of more than 6.0 eV. An example of the material having a bandgap of more than 6.0 eV is a halide of an alkali metal or alkali-earth metal (e.g., lithium fluoride or calcium fluoride), an alkali-earth metal oxide such as magnesium oxide, or silicon dioxide. In this case, to ensure the electron transport property, the electron transport layer 5 has a thickness, for example, not more than 10 nanometers.

The electron transport layer 5 may include a plurality of layers each formed of a material different to each other.

(Third Example of Solar Cell)

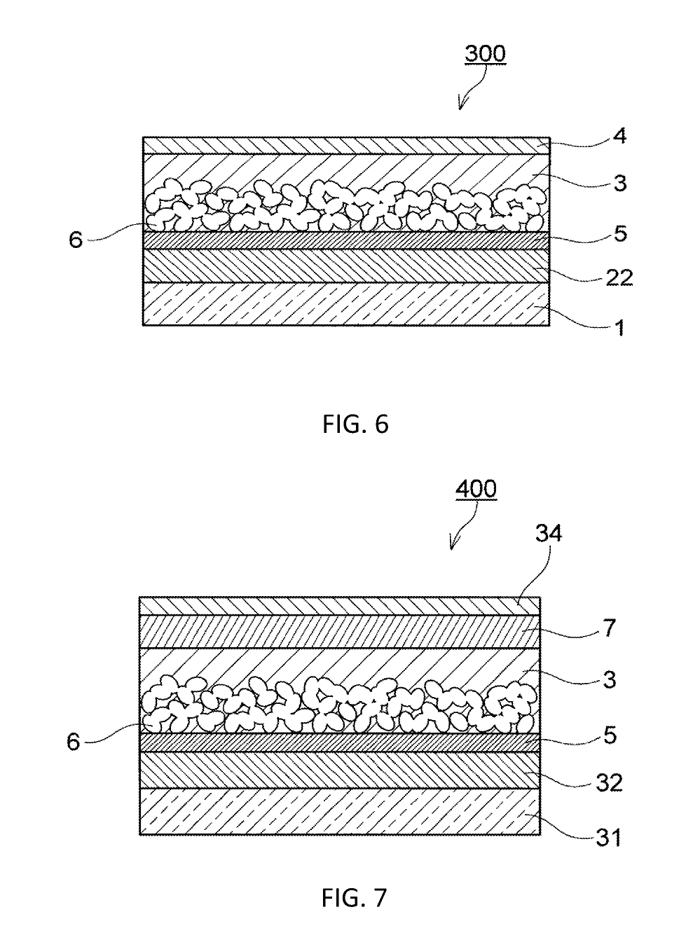

FIG. 6 is a cross-sectional view of the third example of the solar cell according to the present embodiment. Unlike the solar cell 200 shown in FIG. 5, the solar cell 300 comprises a porous layer 6. The common referential signs are assigned to the elements each having the same function and configuration as that of the solar cell 200 and the description thereof will be omitted.

In the solar cell 300, the first electrode 22, the electron transport layer 5, the porous layer 6, the photoabsorber layer 3, and the second electrode 4 are stacked on the substrate 1 in this order. The porous layer 6 contains a porous material. The porous material includes a pore. The solar cell 300 does not have to comprise the substrate 1.

The pore included in the porous layer 6 communicates from a part which is in contact with the photoabsorber layer 3 to a part which is in contact with the electron transport layer 5. The pore included in the porous layer 6 is filled with the material of the photoabsorber layer 3. The material of the photoabsorber layer 3 is in contact with the surface of the electron transport layer 5. Therefore, since the photoabsorber layer 3 is in contact with the electron transport layer 5, electrons migrate directly therebetween.

Hereinafter, the fundamental function effect of the solar cell 300 will be described. When the solar cell 300 is irradiated with light, the light is absorbed into the photoabsorber layer 3. As a result, holes and excited electrons are generated in the photoabsorber layer 3. The excited electrons migrate through the electron transport layer 5 to the first electrode 22. On the other hand, the holes generated in the photoabsorber layer 3 migrate to the second electrode 4. In this way, electric current is taken out from the first electrode 22 and the second electrode 4, which serve as a negative electrode and a positive electrode, respectively.

The porous layer 6 provided on the electron transport layer 5 facilitates the formation of the photoabsorber layer 3. In other words, the material of the photoabsorber layer 3 enters the pore included in the porous layer 6. In this way, the porous layer 6 becomes a foothold of the photoabsorber layer 3. So, the material of the photoabsorber layer 3 is hardly repelled or clumped on the surface of the porous layer 6. Therefore, the photoabsorber layer 3 can be formed as a uniform film.

(Porous Layer 6)

The porous layer 6 becomes a foothold of the formation of the photoabsorber layer 3. The porous layer 6 does not prevent the photoabsorber layer 3 from absorbing the light. In addition, the porous layer 6 does not prevent the electrons from migrating from the photoabsorber layer 3 to the electron transport layer 5. A length of light path of the light passing through the photoabsorber layer 3 is increased due to light scatter caused by the porous layer 6. It is expected that the amounts of the electrons and holes generated in the photoabsorber layer 3 are increased with increase in the length of the light path.

The porous layer 6 contains the porous material. An example of the porous material is a porous material in which insulative or semiconductor particles are connected. An example of the material of the insulative particles is aluminum oxide or silicon oxide. An example of the material of the semiconductor particles is an inorganic semiconductor. The example of the inorganic semiconductor is a metal oxide (including a perovskite oxide), a metal sulfide, or a metal chalcogenide. An example of the metal oxide is an oxide of Cd, Zn, In, Pb, Mo, W, Sb, Bi, Cu, Hg, Ti, Ag, Mn, Fe, V, Sn, Zr, Sr, Ga, Si, or Cr. TiO₂ is desirable. An example of the perovskite oxide is SrTiO₃ or CaTiO₃. An example of the metal sulfide is CdS, ZnS, In₂S₃, SnS, PbS, Mo₂S, WS₂, Sb₂S₃, Bi₂S₃, ZnCdS₂, or Cu₂S. An example of the metal chalcogenide is CdSe, CsSe, In₂Se₃, WSe₂, HgS, SnSe, PbSe, or CdTe.

The porous layer 6 may have a thickness of not less than 0.01 micrometer and not more than 10 micrometers, or not less than 0.1 micrometer and not more than 1 micrometer. The porous layer 6 may have a large surface roughness. In particular, a surface roughness coefficient defined by a value of an effective area/a projected area may be not less than 10, or not less than 100. The effective area is an actual area of a surface of the object. The projected area is an area of a shadow of an object formed posteriorly to the object when light travelling from the front of the object is incident on the object. The effective area can be calculated from a volume calculated from the projected area and the thickness of the object, a specific surface area of the material which constitutes the object, and a bulk density of the object. The specific surface area is measured, for example, by a nitrogen adsorption method.

The solar cell 300 may be fabricated in the same way as that of the solar cell 200. The porous layer 6 is formed on the electron transport layer 5, for example, by a coating method.

The photoabsorber layer 3 is formed as below. A solution containing FAI₃ and the metal Sn is applied to the porous layer 6. Next, the solution is heated to form the photoabsorber layer 3. The solution used in the present method is a solution used for growth of the perovskite compound by the liquid-phase growth method.

(Fourth Example of Solar Cell)

FIG. 7 is a cross-sectional view of the fourth example of the solar cell according to the present embodiment.

Unlike the solar cell 300 shown in FIG. 6, the solar cell 400 comprises a hole transport layer 7. The common referential signs are assigned to the elements each having the same function and configuration as that of the solar cell 300 and the description thereof will be omitted.

In the solar cell 400, a first electrode 32, the electron transport layer 5, the porous layer 6, the photoabsorber layer 3, the hole transport layer 7, and a second electrode 34 are stacked on a substrate 31 in this order. The solar cell 400 does not have to comprise the substrate 31.

Hereinafter, the fundamental function effect of the solar cell 400 will be described.

When the solar cell 400 is irradiated with light, the light is absorbed into the photoabsorber layer 3. As a result, holes and excited electrons are generated in the photoabsorber layer 3. The excited electrons migrate to the electron transport layer 5. On the other hand, the holes generated in the photoabsorber layer 3 migrate to the hole transport layer 7. The electron transport layer 5 and the hole transport layer 7 are electrically connected to the first electrode 32 and the second electrode 34, respectively. In this way, electric current is taken out from the first electrode 32 and the second electrode 34, which serves as a negative electrode and a positive electrode, respectively.

Since the solar cell 400 is provided with the hole transport layer 7 which is present between the photoabsorber layer 3 and the second electrode 34, the second electrode 34 does not have to have the electron block property that the electrons migrating from the photoabsorber layer 3 are blocked. Therefore, the range of the choice of the material of the second electrode 34 is expanded.

Hereinafter, each element of the solar cell 400 will be described. The description of the elements common to those of the solar cell 300 will be omitted.

(First Electrode 32 and Second Electrode 34)

As above described, the second electrode 34 does not have to have the electron block property that the electrons migrating from the photoabsorber layer 3 are blocked. In other words, a material of the second electrode 34 may be a material capable of being in contact with the photoabsorber layer 3. Therefore, the second electrode 34 can be formed so as to be light-transmissive.

At least one electrode selected from the group consisting of the first electrode 32 and the second electrode 34 is light-transmissive and configured in the same way as the first electrode 2 of the solar cell 100.

At least one electrode selected from the group consisting of the first electrode 32 and the second electrode 34 does not have to be light-transmissive. In other words, a light-transmissive material is not necessarily used. The at least one electrode does not have to have a pattern including an opening part through which light travels.

(Substrate 31)

The substrate 31 may have the same configuration as the substrate 1 of the solar cell 100 shown in FIG. 2. When the second electrode 34 is light-transmissive, the substrate 31 does not have to be light-transmissive. An example of the material for the substrate 31 is a metal, a ceramic, or a resin material having a small light-transmissivity.

(Hole Transport Layer 7)

The hole transport layer 7 is composed of an organic substance or an inorganic semiconductor. The hole transport layer 7 may have a plurality of layers each composed of a material different from each other.

In light of the low resistance, it is desirable that the hole transport layer 7 has a thickness of not less than 1 nanometer and not more than 1,000 nanometers, more desirably, not less than 10 nanometers and not more than 50 nanometers. Within this range, the hole transport property is provided sufficiently to generate electric power with high efficiency.

As a formation method of the hole transport layer 7, a coating method or a printing method can be employed. An example of the coating method is a doctor blade method, a bar coating method, a spraying method, a dip coating method, or a spin coating method. An example of the printing method is a screen printing method. If necessary, the hole transport layer 7 is provided by forming a film using a mixture of plural materials, and then, applying a pressure to the film or sintering the film. When the material of the hole transport layer 7 is an organic low-molecular material or an inorganic semiconductor, the hole transport layer 7 may be formed by a vacuum evaporation method.

The hole transport layer 7 may contain a supporting electrolyte and a solvent. The supporting electrolyte and the solvent stabilize the holes included in the hole transport layer 7.

An example of the supporting electrolyte is an ammonium salt or an alkali metal salt. An example of the ammonium salt is tetrabutylammonium perchlorate, tetraethylammonium hexafluorophosphate, an imidazolium salt, or a pyridinium salt. An example of the alkali metal salt is lithium perchlorate or potassium tetrafluoroborate.

The solvent contained in the hole transport layer 7 may have high ionic conductivity. As the solvent, both an aqueous solvent and an organic solvent may be used. In view of more stabilization of the solvent, the organic solvent is desirable. An example of the organic solvent is a heterocyclic compound solvent such as tert-butylpyridine, pyridine, or n-methylpyrrolidone.

As a solvent, an ionic liquid may be used solely. Alternatively, as a solvent, a mixture of an ionic liquid and another solvent may be used. The ionic liquid is desirable in view of its low volatility and high fire retardancy.

An example of the ionic liquid is an imidazolium-type ionic liquid such as 1-ethyl-3-methylimidazolium tetracyanoborate, a pyridine-type ionic liquid, an alicyclic amine-type ionic liquid, an aliphatic amine-type ionic liquid, or an azonium amine-type ionic liquid.

### EXAMPLES

The present disclosure will be described in more detail with reference to the following examples. As will be described below, in the following inventive examples 1-4 and comparative example 1, photoabsorbers each containing a FASnI₃ perovskite compound and a metal Sn were fabricated. Furthermore, their properties were evaluated.

(Fabrication of Photoabsorber)

### Inventive Example 1

In the inventive example 1, the photoabsorber of the inventive example 1 was fabricated by the method shown in FIG. 3A-FIG. 3C. In particular, FAI (product of Tokyo Chemical Industrial, Co., Ltd.) and I₂ (product of Kojundo Chemical Laboratory Co., Ltd.) were add to butanol, and then, dissolved in butanol to prepare a butanol solution. In the butanol solution, the concentration of the FAI is 0.05 mol/L. The concentration of the I₂ is 0.05 mol/L. Apart from this, a glass substrate having a metal Sn film on the surface thereof was prepared. The metal Sn film was formed on the glass substrate by a vapor deposition method. The metal Sn film had a thickness of 150 nanometers. The metal Sn film was immersed in the butanol solution at room temperature for five seconds. As a result, the color of the metal Sn film was changed from gray to black. Subsequently, the glass substrate was heated on a hot plate at 100 degrees Celsius. In this way, a film containing the photoabsorber containing (i) the FASnI₃ perovskite compound and (ii) the metal Sn was provided. All the steps were conducted in the N₂ globe box having an oxygen concentration of not more than 5 ppm, except for the step in which the glass substrate was prepared.

### Inventive Example 2

In the inventive example 2, the film containing the photoabsorber was provided similarly to the inventive example 1, except that the metal Sn film had a thickness of 180 nanometers.

### Inventive Example 3

In the inventive example 3, the film containing the photoabsorber was provided similarly to the inventive example 1, except that the metal Sn film had a thickness of 210 nanometers.

### Inventive Example 4

In the inventive example 4, the film containing the photoabsorber was provided similarly to the inventive example 1, except that the metal Sn film had a thickness of 300 nanometers.

### Comparative Example 1

SnI₂ (product of Sigma-Aldrich), SnF₂ (product of Kojundo Chemical Laboratory Co., Ltd.), and FAI (product of Tokyo Chemical Industrial, Co., Ltd.) were dissolved in an organic solvent to prepare a mixture solution. The organic solution is a mixture of DMSO and DMF (volume ratio 1:1).

The concentration of the SnI₂, SnF₂, and FAI contained in the mixture solution was 1.35 mol/L, 0.15 mol/L, and 1.5 mol/L, respectively.

Next, the mixture solution was applied to a glass substrate by a spin-coat method. Subsequently, the glass substrate was heated on the hot plate at 80 degrees Celsius for 30 minutes. In this way, a film containing the photoabsorber containing the perovskite compound was provided. Note that the perovskite compound contained in the photoabsorber provided in the comparative example 1 was FASnI₃ which did not contain the metal Sn. All the steps were conducted in the N₂ globe box having an oxygen concentration of not more than 5 ppm.

(Crystal Structure Analysis)

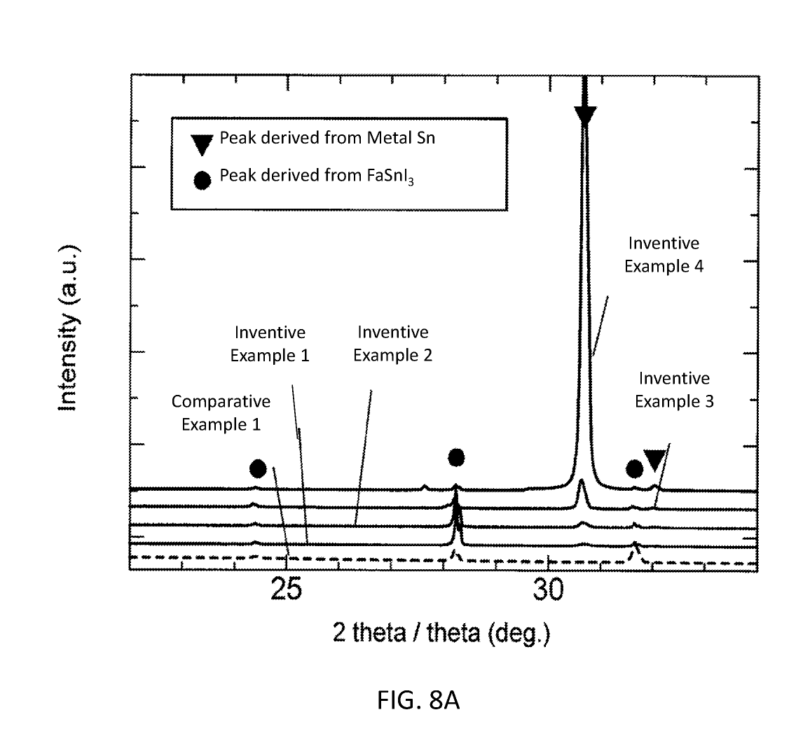

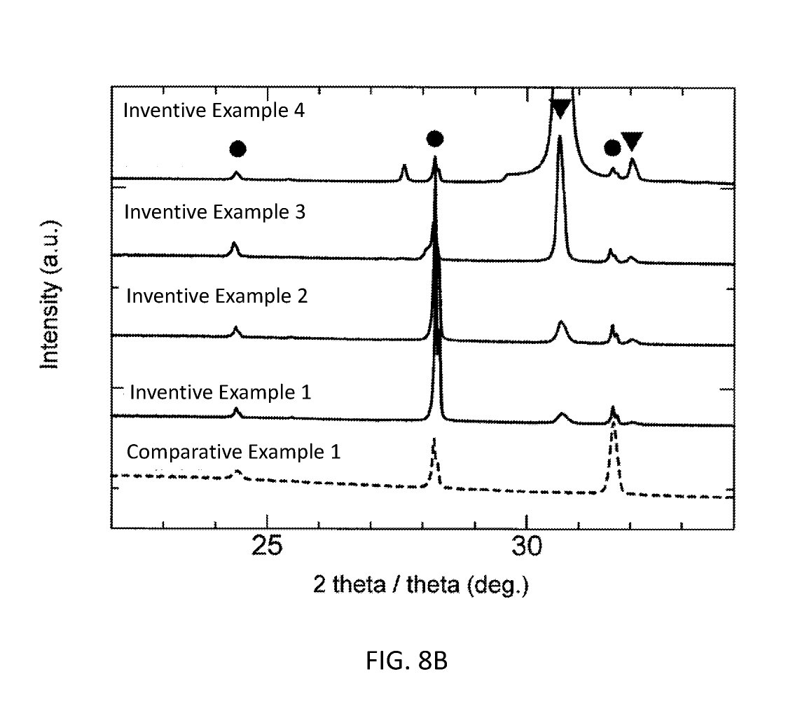

The photoabsorbers of the inventive examples 1-4 and the comparative example 1 were subjected to an X-ray diffraction (hereinafter, referred to as “XRD”) measurement using a CuKα ray. FIG. 8A and FIG. 8B are graphs each showing the XRD measurement results provided in the inventive examples 1-4 and the comparative example 1. The horizontal axis and the vertical axis represent a diffraction angle 2θ and an X-ray diffraction intensity, respectively. FASnI₃ has an orthorhombic crystal structure at room temperature. In FIG. 8A and FIG. 8B, black circles and inversed black triangles are added to the peaks derived from FASnI₃ and the metal Sn, respectively.

As is clear from FIG. 8A and FIG. 8B, similarly to the case of the perovskite compound of the comparative example 1, since each of the compounds of the inventive examples 1-4 has a peak at a diffraction angle 2θ of 28°-29°, each of the compounds of the inventive examples 1-4 has a perovskite structure. In other words, each of the photoabsorbers of the inventive examples 1-4 and the comparative example 1 contains the FASnI₃ perovskite compound. Furthermore, since each of the photoabsorbers of the inventive examples 1-4 has a peak at a diffraction angle 2θ of 30°-31°, each of the compounds of the inventive examples 1-4 contains the metal Sn.

With regard to the XRD pattern of the inventive examples 1-4 and the comparative example 1, an intensity ratio of the maximum diffraction intensity within a second range to the maximum diffraction intensity within a first range was calculated. The first range is a range within which the diffraction angle 2θ is 24.2°-24.4°. The second range is a range within which the diffraction angle 2θ is 30.5°-30.7°. The calculated intensity ratio is shown in Table 1.

As described above, the peak derived from the perovskite compound appears within the first range. The peak derived from the metal Sn appears within the second range. The peak derived from the metal Sn appears in the inventive examples 1-4, whereas no peak derived from the metal Sn appears in the comparative example 1, since the metal Sn is not contained. Therefore, in the comparative example 1, the intensity ratio within the second range is small. On the other hand, as is clear from FIG. 8A and FIG. 8B, as the metal Sn film is thicker, the peak derived from the metal Sn is higher. Furthermore, as the metal Sn film is thicker, the intensity ratio is greater.

(Composition Analysis Result)

The photoabsorbers of the inventive examples 1, 2, and 4 and the comparative example 1 were subjected to composition analysis using the X-ray photoelectron spectroscopy (hereinafter, referred to as “XPS”) measurement. The composition analysis results in the inventive examples 1, 2, and 4 and the comparative example 1 are shown in Table 1 and Table 2. A molar ratio of tin to iodine in each of the photoabsorbers of the inventive examples 1-2 and the comparative example 1 is approximately one-third. This means that FASnI₃ is formed, as indicated in its composition formula. Since each of the photoabsorbers of the inventive examples 1, 2, and 4 contains the metal Sn, the molar ratio of tin to iodine in each of the photoabsorbers of the inventive examples 1, 2, and 4 is higher than that of the comparative example 1. The molar ratio of tin to iodine in the photoabsorber of the inventive example 4 is much more than one-third, since the metal Sn content of the photoabsorber of the inventive example 4 is significantly high. As is clear from the results of the above-mentioned crystal structure analysis, the photoabsorber of the inventive example 4 contains the perovskite compound of FASnI₃, similarly to the case of the inventive examples 1-2.

(Light-Transmissivity Measurement)

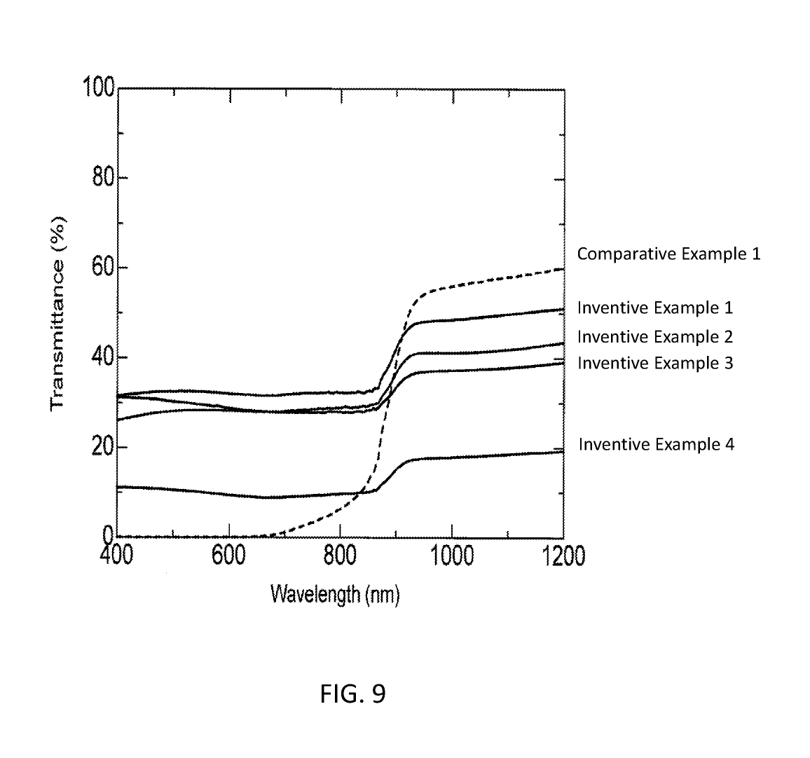

The light-transmissivity of each of the films of the photoabsorbers of the inventive examples 1-4 and the comparative example 1 was measured. FIG. 9 is a graph showing the results of the light-transmissivity of the films of the photoabsorbers of the inventive examples 1-4 and the comparative example 1. The horizontal axis and the vertical axis represent a wavelength and the light-transmissivity, respectively. Note that the light-transmissivity does not reach 100% due to reflection and scattering on the surface of the film.

As understood from FIG. 9, in the comparative example 1, the light-transmissivity at a wavelength of 1,000 nanometers is 54%. On the other hand, at a wavelength of 1,000 nanometers, each of the photoabsorbers of the inventive examples 1-4 has lower light-transmissivity than the photoabsorber of the comparative example 1 due to the reflection of the metal Sn contained in the layer of the photoabsorber. The light-transmissivity is decreased with an increase in the metal Sn content.

Table 2 shows a reflection ratio by the metal Sn. The reflection ratio is calculated on the basis of the light-transmissivity measurement. The amount of the reflected light is increased with an increase in the metal Sn content in the photoabsorber. As a result, the amount of the light absorbed into the photoabsorber layer is decreased. In order to improve the conversion efficiency of the solar cell, the metal Sn content of the photoabsorber contained in the photoabsorber layer of the solar cell can be configured to fall within an appropriate range in light of the effect of the reflection by the metal Sn. For example, the reflection ratio is lowered to a relatively low value, if the photoabsorber contains the metal Sn at the above-mentioned intensity ratio of more than 48% and less than 1,130%, desirably, not less than 80% and not more than 510% (the photoabsorbers in the inventive example 1 to 3). Therefore, the photoabsorber containing the metal Sn within such a range would improve the conversion efficiency of the solar cell significantly more.

(Carrier Density Measurement)

The photoabsorbers of the inventive examples 1-4 and the comparative example 1 were subjected to hole effect measurement to calculate the carrier density thereof.

Table 2 shows the carrier density of the photoabsorbers of the inventive examples 1-4 and the comparative example 1 calculated based on the hole effect measurement by a Van der Pauw method. The photoabsorber of the comparative example 1 has a high carrier density of 10¹⁸ cm⁻³. On the other hand, in the photoabsorbers of the inventive examples 1-4, the Sn vacancies is prevented from being generated, since the metal Sn is contained. So, each of the photoabsorbers of the inventive examples 1-4 has low carrier density of less than 10¹⁵ cm⁻³. Therefore, it is expected that the solar cell including at least one of the photoabsorber of any one of the inventive examples 1-4 has high conversion efficiency.

(Conversion Efficiency)

The conversion efficiency of the photoabsorbers of the inventive examples 1-3 and the comparative example 1 is shown in Table 2. The conversion efficiency is calculated using a simulator. For the calculation of the conversion efficiency, the present inventors took into account the reflection ratio and the carrier density of the metal Sn. The reflection ratio and the carrier density were calculated on the basis of the above-mentioned light transmissivity measurement and the carrier density measurement, respectively. The photoabsorber of the comparative example 1 has low conversion efficiency of 1.3%, since the carrier density thereof is high. On the other hand, each of the photoabsorbers of the inventive examples 1-3 has high conversion efficiency.

TABLE 1

| | Thickness of Metal | | Molar ratio |
|---|---|---|---|
| | Sn Film | Intensity | of Tin to |
| | (nanometers) | ratio (%) | Iodine |
| Inventive Example 1 | 150 | 80 | 0.353 |
| Inventive Example 2 | 180 | 130 | 0.380 |
| Inventive Example 3 | 210 | 510 | (not measured) |
| Inventive Example 4 | 300 | 1,130 | 0.986 |
| Comparative | 0 | 48 | 0.317 |
| Example 1 | | | |

TABLE 2

| | | | Calculation |
|---|---|---|---|
| | Reflection Ratio | Carrier | Value of |
| | of Metal | Density | Conversion |
| | Sn Film (%) | (cm⁻³) | Efficiency (%) |
| Inventive Example 1 | 13 | 7.46 × 10⁹ | 7.0 |
| Inventive Example 2 | 27 | 3.69 × 10¹¹ | 5.5 |
| Inventive Example 3 | 33 | 1.15 × 10¹³ | 4.3 |
| Inventive Example 4 | 68 | 1.79 × 10¹⁴ | (Not calculated) |
| Comparative | 0 | 7.01 × 10¹⁸ | 1.3 |
| Example 1 | | | |

As understood from the above results, the solar cell including the photoabsorber containing the Sn-type perovskite compound and the metal Sn has high conversion efficiency.

### INDUSTRIAL APPLICABILITY

The photoabsorber of the present disclosure improves the conversion efficiency of the solar cell, when the photoabsorber is used for the photoabsorber layer of the solar cell.

### REFERENTIAL SIGNS LIST

1, 31 Substrate
2, 22, 32 First Electrode
3 Photoabsorber Layer
4, 34 Second Electrode
5 Electron Transport Layer
6 Porous Layer
7 Hole Transport Layer
10 Black Solution (i.e., First Solution)
11 Glass Substrate
12 Metal Sn Film
100, 200, 300, 400 Solar Cell

1. A photoabsorber, containing:
a perovskite compound represented by the composition formula ABX₃,
where
A represents a monovalent cation,
B represents a divalent cation including a Sn cation, and
X represents a halogen anion; and
a metal Sn.

2. The photoabsorber according to claim 1, wherein
in an X-ray diffraction measurement result using an CuKα ray, an intensity ratio of the maximum diffraction intensity within a second range to the maximum diffraction intensity within a first range is more than 48% and less than 1,130%,
where
the first range is a range within which a diffraction angle 2θ is 24.2°-24.4°, and
the second range is a range within which the diffraction angle 2θ is 30.5°-30.7°.

3. The photoabsorber according to claim 2, wherein
the intensity ratio is not less than 80% and not more than 510%.

4. The photoabsorber according to claim 1, wherein
a molar ratio of the Sn cation to the halogen anion is more than 0.317 and not more than 0.986.

5. A solar cell, comprising:
a first electrode;
a second electrode; and
a photoabsorber layer containing a photoabsorber according to claim 1,
wherein
the photoabsorber layer is present between the first electrode and the second electrode; and
at least one selected from the group consisting of the first electrode and the second electrode is light-transmissive.
